(19) United States
(12) Patent Application Publication
(10) Pub. No.: US 2025/0096145 A1
(43) Pub. Date: Mar. 20, 2025

(54) ELECTRONIC PACKAGING STRUCTURE

(71) Applicant: Unimicron Technology Corp., Taoyuan City (TW)

(72) Inventors: Chin-Sheng Wang, Taoyuan City (TW); Ra-Min Tain, Hsinchu County (TW); Chih-Kai Chan, Taoyuan City (TW); Chun-Hsien Chien, Hsinchu City (TW)

(73) Assignee: Unimicron Technology Corp., Taoyuan City (TW)

(21) Appl. No.: 18/964,695

(22) Filed: Dec. 2, 2024

Related U.S. Application Data
(63) Continuation-in-part of application No. 17/979,754, filed on Nov. 2, 2022, now Pat. No. 12,200,861.
Application No. 17/979,754 is a continuation-in-part of application No. 17/674,837, filed on Feb. 18, 2022, now Pat. No. 11,690,173.
(60) Provisional application No. 63/346,912, filed on May 30, 2022.
(60) Provisional application No. 63/213,667, filed on Jun. 22, 2021.
(60) Provisional application No. 63/605,590, filed on Dec. 4, 2023.

(30) Foreign Application Priority Data
Dec. 27, 2021 (TW) 110148855
Sep. 27, 2022 (TW) 111136488
Nov. 7, 2024 (TW) 113142653

(51) Int. Cl. H01L 23/538; H01L 23/13; H01L 23/373; H01L 25/03

(52) U.S. Cl. CPC H01L 23/5385; H01L 23/13; H01L 23/373; H01L 25/03

(57) ABSTRACT

An electronic packaging structure including a first circuit structure and a second circuit structure is provided. An electronic component is disposed between the first circuit structure and the second circuit structure. At least one of the first circuit structure and the second circuit structure (for example, the second circuit structure) has a cavity. The electronic component is embedded in the cavity, and may be encapsulated between the first circuit structure and the second circuit structure.

### CROSS-REFERENCE TO RELATED APPLICATION

This application is a continuation-in-part application of and claims the priority benefit of U.S. application Ser. No. 17/979,754, filed on Nov. 2, 2022, now pending. The prior U.S. application Ser. No. 17/979,754 claims the priority benefits of U.S. provisional application Ser. No. 63/346,912, filed on May 30, 2022, and Taiwan application serial no. 111136488, filed on Sep. 27, 2022. The prior U.S. application Ser. No. 17/979,754 is also a continuation-in-part application of and claims the priority benefit of U.S. application Ser. No. 17/674,837, filed on Feb. 18, 2022, now patented, which also claims the priority benefits U.S. provisional application Ser. No. 63/213,667, filed on Jun. 22, 2021, and Taiwan application serial no. 110148855, filed on Dec. 27, 2021. This application also claims the priority benefits of U.S. provisional application Ser. No. 63/605,590, filed on Dec. 4, 2023, and Taiwan application serial no. 113142653, filed on Nov. 7, 2024. The entirety of each of the above-mentioned patent applications is hereby incorporated by reference herein and made a part of this specification.

### BACKGROUND

### Technical Field

The disclosure relates to an electronic packaging structure, and particularly relates to an electronic packaging structure having an electronic component embedded between multiple circuit structures.

### Description of Related Art

Thanks to the advancement of technology, electronic products become increasingly versatile, and there is a growing reliance on electronic mobile devices. In response to the demand for miniaturization and lightweight of electronic products, the antenna structure and the chip packaging structure are integrated to achieve the miniaturization and lightweight of electronic products. Generally speaking, for the current chip packaging structure with an antenna structure, the chip is typically disposed on a circuit board and covered with a molding material so as to form a chip packaging structure. The antenna structure is then disposed on the chip packaging structure and electrically connected to the circuit board through conductive pillars or conductive balls that penetrate the molding material in the chip packaging structure. However, in the packaging structure, electronic components may not be well protected; and/or the packaging structure may not effectively reduce or prevent radio frequency signals from dispersing during transmission, and may be larger in size.

### SUMMARY

The disclosure provides an electronic packaging structure, which properly protects an electronic component included therein.

An electronic packaging structure according to one embodiment of the disclosure includes a first circuit structure, a second circuit structure, and a first electronic component. The first electronic component is located between the first circuit structure and the second circuit structure. At least one of the first circuit structure and the second circuit structure (for example, the second circuit structure) has a cavity. The first electronic component is embedded in the cavity, and may be encapsulated between the first circuit structure and the second circuit structure.

Based on the above, in the electronic packaging structure, the electronic component (for example, the first electronic component) is located between the first circuit structure and the second circuit structure, and at least part of the electronic component may be located in the cavity of one of the circuit structures. Therefore, the electronic component is properly protected, which reduces the possibility of damage or deterioration of the electronic component and improves the quality of the electronic packaging structure.

### BRIEF DESCRIPTION OF THE DRAWINGS

FIG. 1A to FIG. 1D are partial cross-sectional views showing part of the manufacturing method of the electronic packaging structure according to the first embodiment of the disclosure.

FIG. 2 is a partial cross-sectional view of the electronic packaging structure according to the second embodiment of the disclosure.

FIG. 3 is a partial cross-sectional view of the electronic packaging structure according to the third embodiment of the disclosure.

### DESCRIPTION OF THE EMBODIMENTS

Embodiments of the disclosure will be described in detail with reference to the accompanying drawings, but the embodiments are not intended to limit the scope of the disclosure. Furthermore, the drawings are for illustrative purposes only, and may not be drawn to scale.

Moreover, terms such as “include” and “have” used in the specification are all open-ended terms, which mean “including but not limited to.”

It should be understood that although terms such as “first,” “second,” and “third” may be used in the specification to describe various elements, components, areas, layers, and/or parts, these elements, components, areas, layers, and/or parts are not limited by these terms. These terms are only used to distinguish one element, component, area, layer, or part from another element, component, area, layer, or part. Therefore, a first element, component, area, layer, or part mentioned below may be referred to as a second element, component, area, layer, or part without departing from the teachings of the disclosure.

Directional terms used in the specification, such as “upper,” “lower,” “top,” and “bottom,” merely refer to the orientation in the accompanying drawings. Therefore, the directional terms used are for illustrative purposes and are not intended to limit the disclosure.

Each of the accompanying drawings illustrates the general characteristics of the methods, structures, and/or materials used in specific embodiments. However, these drawings should not be interpreted as defining or limiting the scope or nature covered by these embodiments. For example, for clarity, the relative dimensions, thicknesses, and positions of various layers, areas, and/or structures may be reduced or enlarged.

In the following embodiments, the same or similar elements will be denoted by the same or similar reference numerals, and redundant descriptions will be omitted. Moreover, features from different embodiments may be combined with each other without conflict, and simple equivalent variations and modifications made according to the specification or claims are still within the scope of the disclosure.

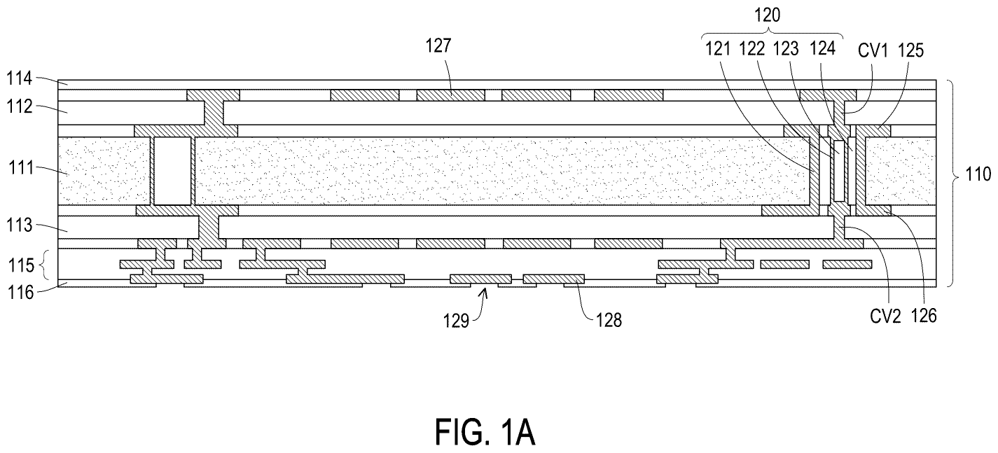

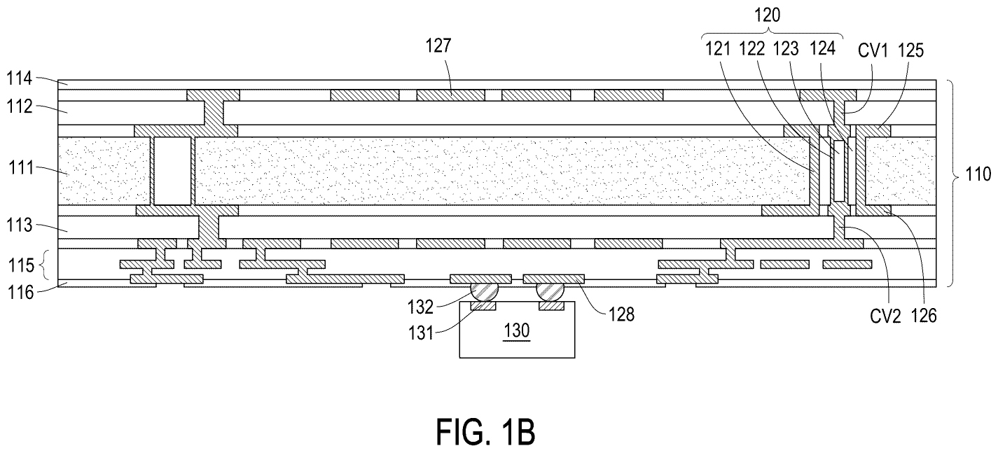

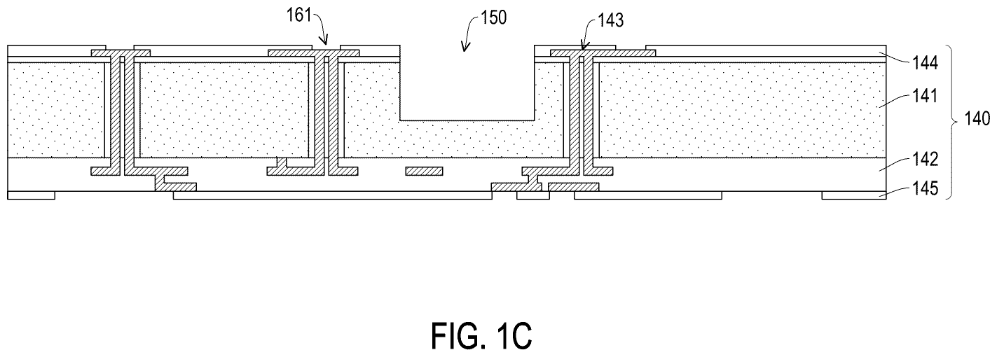

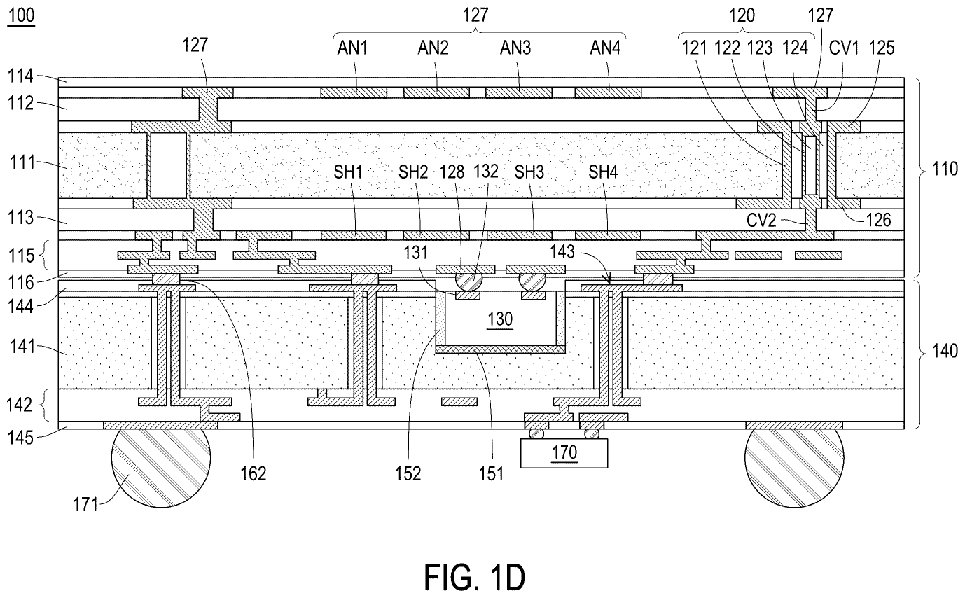

FIG. 1A to FIG. 1D are partial cross-sectional views showing part of the manufacturing method of the electronic packaging structure according to the first embodiment of the disclosure.

### <First Circuit Structure>

FIG. 1A is a schematic view showing the first circuit structure according to the first embodiment of the disclosure.

Referring to FIG. 1A, a first circuit structure 110 includes a first core layer 111. The first core layer 111 may include a polymer glass fiber composite substrate, a glass substrate, an insulating silicon substrate, a polyimide (PI) film, or a glass fiber composite substrate, but the disclosure is not limited thereto.

The first core layer 111 includes at least one coaxial conductive via 120. In one embodiment, the coaxial conductive via 120 includes an outer conductive layer 121, a first dielectric layer 124, and an inner conductive layer 122. The first dielectric layer 124 is located between the outer conductive layer 121 and the inner conductive layer 122. The outer conductive layer 121 at least partially surrounds the inner conductive layer 122. The outer conductive layer 121 and the inner conductive layer 122 are electrically separated from each other. In one embodiment, the coaxial conductive via 120 further includes a second dielectric layer 123. The inner conductive layer 122 is located between the first dielectric layer 124 and the second dielectric layer 123. In one embodiment, the first core layer 111 further includes other conductive vias, which may include solid metal pillars or hollow metal pillars with an insulating material filled in the hollow metal pillars, but the disclosure is not limited thereto.

In one embodiment, the first circuit structure 110 includes the first core layer 111, and a corresponding wiring layer and a corresponding insulation layer located on the upper side and the lower side of the first core layer 111. In one embodiment, the first circuit structure 110 further includes a redistribution layer 115. The coaxial conductive via 120 penetrates the first core layer 111 to electrically connect the wiring in the wiring layer and/or the wiring in the redistribution layer 115.

In one embodiment, the first circuit structure 110 includes a second upper insulation layer 114, a second upper wiring layer 127, a first upper insulation layer 112, a first upper wiring layer 125, a first lower wiring layer 126, a first lower insulation layer 113, a redistribution layer 115, a second lower wiring layer 128, and a second lower insulation layer 116. The inner conductive layer 122 of the coaxial conductive via 120 is electrically connected to the corresponding wiring in the second upper wiring layer 127 and the corresponding wiring in the second lower wiring layer 128. The outer conductive layer 121 of the coaxial conductive via 120 is electrically connected to the corresponding wiring in the first upper wiring layer 125 and the corresponding wiring in the first lower wiring layer 126. The first upper insulation layer 112 is disposed between the first upper wiring layer 125 and the second upper wiring layer 127, and has a via CV1 disposed in the first upper insulation layer 112 to electrically connect the corresponding wiring in the first upper wiring layer 125 and the corresponding wiring in the second upper wiring layer 127. The first lower insulation layer 113 is disposed between the first lower wiring layer 126 and the second lower wiring layer 128, and has a via CV2 disposed in the first lower insulation layer 113 to electrically connect the corresponding wiring in the first lower wiring layer 126 and the corresponding wiring in the second lower wiring layer 128. When the via CV2 is electrically connected to the second lower wiring layer 128, an electrical signal is allowed to be connected to the redistribution layer 115.

In one embodiment, the second upper wiring layer 127, the first upper wiring layer 125, the first lower wiring layer 126, the redistribution layer 115, and the second lower wiring layer 128 include a conductive material such as copper, titanium, tungsten, aluminum, a combination thereof, or similar materials.

In one embodiment, insulation layers (not shown) are disposed to cover the corresponding wiring layers, such as the insulation layer covering the first upper wiring layer 125 and the insulation layer covering the first lower wiring layer 126. In one embodiment, the insulation layers (not shown) may include Bismaleimide Triazine resin (BT resin), Epoxy Glass Fiber Unclad Laminate (for example, FR4), polyimide coating layers, or polyimide dry films.

In one embodiment, the outermost insulation layer (for example, the second upper insulation layer 114 and/or the second lower insulation layer 116) may be called a solder mask, which is used to reduce or decrease oxidation and prevent forming a solder bridge between closely spaced pads. The outermost insulation layer (for example, the second upper insulation layer 114 and/or the second lower insulation layer 116) may include epoxy resin.

In one embodiment, the bottom surface of the first circuit structure 110 has at least one opening 129, and the opening 129 exposes part of the corresponding wiring in the second lower wiring layer 128.

It should be understood that FIG. 1A only illustratively depicts the insulation layers, wiring layers, and conductive vias of the first circuit structure 110, but is not intended to limit the disclosure. The number, position, and pattern design (for example, layout design) of the insulation layers, wiring layers, and conductive vias may be adjusted according to actual requirements.

### <Integration of First Circuit Structure and Electronic Component>

FIG. 1B is a schematic view showing the integration of the first circuit structure and the electronic component according to the first embodiment of the disclosure.

Referring to FIG. 1B, at least one electronic component 130 is disposed on the bottom surface of the first circuit structure 110 (for example, the lower side in the drawing), and the electronic component 130 is electrically connected to part of the corresponding wiring in the second lower wiring layer 128 exposed by the opening 129.

In one embodiment, the electronic component 130 is electrically connected to the corresponding wiring in the second lower wiring layer 128 by the corresponding conductive pad 131 and conductive connecting component 132. The conductive connecting component 132 may include a conductive pillar (for example, copper pillar), solder (for example, solder ball), conductive adhesive (for example, silver paste or solder paste), or other suitable conductive components.

In one embodiment, the electronic component 130 is electrically connected to the corresponding wiring in the second lower wiring layer 128 by flip-chip bonding.

In one embodiment, the electronic component 130 includes a chip. In one embodiment, the chip may include a communication chip or a chip with a communication module. In one embodiment, the electronic component 130 is configured to receive and/or transmit signals by the corresponding antenna. In one embodiment, the electronic component 130 is a packaged component (for example, a System on Chip, SoC), which integrates several active components.

In one embodiment, the electronic component 130 includes a passive component. The electronic component 130 may include a resistor, a capacitor, an inductor, and/or a fuse.

### <Second Circuit Structure>

FIG. 1C is a schematic view showing the second circuit structure according to the first embodiment of the disclosure.

Referring to FIG. 1C, a second circuit structure 140 includes a second core layer 141. The second core layer 141 may include a metal substrate, including copper, aluminum, iron, steel alloy, a combination thereof, or similar conductive materials, but the disclosure is not limited thereto.

In one embodiment, the second circuit structure 140 includes the second core layer 141, a corresponding wiring layer and a corresponding insulation layer located on the upper side and the lower side of the second core layer 141, and the outermost third upper insulation layer 144 and third lower insulation layer 145. In one embodiment, the circuit structure 140 further includes a redistribution layer 142. In one embodiment, the second circuit structure 140 has at least one conductive via 143. The conductive via 143 penetrates the second core layer 141 to electrically connect the corresponding wiring in the wiring layer and the corresponding wiring in the redistribution layer 142.

In one possible embodiment, the conductive via 143 is a coaxial conductive via. The structure of the coaxial conductive via may be the same as or similar to the structure of the coaxial conductive via 120.

In one possible embodiment, the conductive via 143 also includes a solid metal pillar or a hollow metal pillar with an insulating material filled in the hollow metal pillar, but the disclosure is not limited thereto.

In one embodiment, the redistribution layer 142 and the corresponding wiring layers located on the upper side and the lower side of the second core layer 141 include a conductive material such as copper, titanium, tungsten, aluminum, a combination thereof, or similar materials.

In one embodiment, the corresponding insulation layers located on the upper side and the lower side of the second core layer 141 cover the corresponding wiring layers. In one embodiment, the insulation layers may include Bismaleimide Triazine resin (BT resin), Epoxy Glass Fiber Unclad Laminate (for example, FR4), polyimide coating layers, or polyimide dry films.

In one embodiment, the third upper insulation layer 144 and the third lower insulation layer 145 may be called solder masks, which are used to reduce or decrease oxidation and prevent forming a solder bridge between closely spaced pads. The outermost third upper insulation layer 144 and third lower insulation layer 145 may include epoxy resin.

In one embodiment, the top surface of the second circuit structure 140 has a cavity 150. The cavity 150 is a blind hole which does not penetrate the second core layer 141.

In one embodiment, the top surface of the second circuit structure 140 further has at least one opening 161, and the opening 129 exposes part of the corresponding wiring in the wiring layer. In one embodiment, the bottom surface of the second circuit structure 140 may have at least one opening (not shown), and the opening exposes part of the corresponding wiring in the redistribution layer 142.

It should be understood that FIG. 1C only illustratively depicts the insulation layers, wiring layers, and conductive vias of the second circuit structure 140, but is not intended to limit the disclosure. The number, position, and pattern design of the insulation layers, wiring layers, and conductive vias may be adjusted according to actual requirements.

### <Integration of Second Circuit Structure and Electronic Component>

FIG. 1D is a schematic view showing the electronic packaging structure according to the first embodiment of the disclosure.

Referring to FIG. 1D, at least one electronic component 170 is disposed below the bottom surface of the second circuit structure 140, and the electronic component 170 is electrically connected to the corresponding wiring in the wiring layer exposed by the opening (not shown).

In one embodiment, the electronic component 170 is electrically connected to the corresponding wiring in the wiring layer by a conductive connecting component (not shown).

The conductive connecting component may include a conductive pillar (for example, copper pillar), solder (for example, solder ball), conductive adhesive (for example, silver paste or solder paste), or other suitable conductive components.

In one embodiment, the electronic component 170 includes a chip. In one embodiment, the chip includes a communication chip or a chip with a communication module. In one embodiment, the electronic component 170 is configured to receive and/or transmit signals by the corresponding antenna. In one embodiment, the electronic component 170 is a packaged component (for example, a System on Chip, SoC), which integrates several active components.

In one embodiment, the electronic component 170 includes a passive component.

The electronic component 170 may include a resistor, a capacitor, an inductor, and/or a fuse.

### <Electronic Packaging Structure>

Referring to FIG. 1D, an electronic packaging structure 100 is provided. The electronic packaging structure 100 may be a packaging structure that bonds the first circuit structure 110 and the second circuit structure 140, but the disclosure is not limited thereto.

The electronic component 130 may be disposed in the cavity 150. In one embodiment, there may be a gap between the electronic component 130 and the cavity 150, so a thermal interface material 151 may be filled in the gap. The thermal interface material 151 may fill part of the gap between the electronic component 130 and the bottom surface of the cavity 150. Moreover, in one embodiment where a metal substrate is used as the second core layer 141, the thermal interface material may improve thermal conduction efficiency and reduce interface thermal resistance.

In one embodiment, the thermal interface material 151 may include thermally conductive adhesive, thermal paste, a thermally conductive adhesive film, or a thermally conductive adhesive tape with a thermally conductive material (for example, thermally conductive particles), but the disclosure is not limited thereto.

In one embodiment, after filling the gap between the electronic component 130 and the bottom surface of the cavity 150 with the thermal interface material 151, the gap is further filled with a dielectric material 152. The dielectric material 152 may fill the gap between the electronic component 130 and the cavity 150 to avoid the possibility of short circuits.

In one embodiment, the dielectric material 152 may include a resin material, but the disclosure is not limited thereto.

In one embodiment, conductive adhesive 162 is applied to at least one opening 129 in the first circuit structure 110 and at least one opening 161 in the second circuit structure 140. The conductive adhesive 162 bonds the first circuit structure 110 and the second circuit structure 140 and electrically connects the corresponding wirings.

In one embodiment, the conductive adhesive 162 may include metal alloy, solder paste, silver adhesive, or other suitable conductive adhesive, but the disclosure is not limited thereto.

In one embodiment, a conductive terminal 171 is disposed in at least one opening (not shown) on the bottom surface of the second circuit structure 140. The conductive terminal 171 is electrically connected to the corresponding wiring in the redistribution layer 142.

Referring to FIG. 1D, the electronic packaging structure 100 includes the first circuit structure 110, the second circuit structure 140, and the first electronic component 130. The first electronic component 130 is located between the first circuit structure 110 and the second circuit structure 140. At least one of the first circuit structure 110 and the second circuit structure 140 (for example, the second circuit structure 140) has the cavity 150. The first electronic component 130 is embedded in the cavity 150, and may be encapsulated between the first circuit structure 110 and the second circuit structure 140. The first circuit structure 110 includes the coaxial conductive via 120. The coaxial conductive via 120 includes the inner conductive layer 122, the outer conductive layer 121, and the first dielectric layer 124. The first dielectric layer 124 is located between the inner conductive layer 122 and the outer conductive layer 121.

In one embodiment, the inner conductive layer 122 and the outer conductive layer 121 are electrically separated from each other.

In one embodiment, the inner conductive layer 122 may be electrically connected to the corresponding wiring and/or electronic component (for example, the first electronic component 130 or the second electronic component 170) in the second upper wiring layer 127. In one embodiment, the inner conductive layer 122 is configured for signal transmission.

In one embodiment, part of the wiring in the second upper wiring layer 127 includes an antenna AN1, an antenna AN2, an antenna AN3, and an antenna AN4. In the cross-section illustrated in FIG. 1D or other similar drawings, the antenna AN1, the antenna AN2, the antenna AN3, and the antenna AN4 appear to be separated from each other, but these antennas may actually be different portions of the same antenna. For example, in a top view, the antenna may be spiral, and the spiral antenna may appear as shown in FIG. 1D in a cross-section.

In one embodiment, the outer conductive layer 121 is grounded. The grounding may include floating grounding or physical grounding.

In one embodiment, when the inner conductive layer 122 is configured for signal transmission (for example, signal connection between the aforementioned antenna and the first electronic component 130), the grounded outer conductive layer 121 may be considered as an electromagnetic interference shielding (EMI shielding) layer. As a result, during signal transmission, the outer conductive layer 121 may reduce the interference of the transmitted signal with other components, and/or reduce the possibility of the transmitted signal being interfered with by other components, thereby improving signal quality.

In one embodiment, the electronic component 100 further includes a shielding circuit SH1, a shielding circuit SH2, a shielding circuit SH3, and a shielding circuit SH4. In the cross-section illustrated in FIG. 1D or other similar drawings, the shielding circuit SH1, the shielding circuit SH2, the shielding circuit SH3, and the shielding circuit SH4 appear to be separated from each other, but these shielding circuits may actually be different portions of the same shielding circuit. For example, in a top view, the shielding circuit may be spiral, and the spiral shielding circuit may appear as shown in FIG. 1D in a cross-section.

In one embodiment, the shielding circuit SH1, the shielding circuit SH2, the shielding circuit SH3, and the shielding circuit SH4 are disposed in the first circuit structure 110. In one embodiment, the antenna AN1, the antenna AN2, the antenna AN3, and the antenna AN4 and the shielding circuit SH1, the shielding circuit SH2, the shielding circuit SH3, and the shielding circuit SH4 are respectively located on two opposite sides of the first core layer 111 (for example, the upper side or the lower side in FIG. 1D). In one embodiment, the shielding circuit SH1, the shielding circuit SH2, the shielding circuit SH3, and the shielding circuit SH4 may be portions of the wiring in the redistribution layer 115 of the first circuit structure 110.

In one embodiment, along a direction parallel to the thickness of the first circuit structure 100, the antenna AN1, the antenna AN2, the antenna AN3, and the antenna AN4 and the shielding circuit SH1, the shielding circuit SH2, the shielding circuit SH3, and the shielding circuit SH4 at least partially overlap. In one embodiment, along a direction parallel to the thickness of the first circuit structure 100, the antenna AN1, the antenna AN2, the antenna AN3, and the antenna AN4 substantially completely overlap the shielding circuit SH1, the shielding circuit SH2, the shielding circuit SH3, and the shielding circuit SH4. That is, in the aforementioned direction, the projected outline of the pattern of the antenna AN1, the antenna AN2, the antenna AN3, and the antenna AN4 substantially overlaps the projected outline of the pattern of the shielding circuit SH1, the shielding circuit SH2, the shielding circuit SH3, and the shielding circuit SH4; or the projected outline of the pattern of the antenna AN1, the antenna AN2, the antenna AN3, and the antenna AN4 is within the projected outline of the pattern of the shielding circuit SH1, the shielding circuit SH2, the shielding circuit SH3, and the shielding circuit SH4.

In one embodiment, the shielding circuit SH1, the shielding circuit SH2, the shielding circuit SH3, and the shielding circuit SH4 are grounded and they may be merged into a single ground plane. In one embodiment, the shielding circuit may serve as a dummy pattern without signal transmission purpose.

In one embodiment, along a direction parallel to the thickness of the first circuit structure 100, there is no other conductor used for electrical transmission (for example, signal transmission or power transmission) between the antenna AN1, the antenna AN2, the antenna AN3, and the antenna AN4 and the shielding circuit SH1, the shielding circuit SH2, the shielding circuit SH3, and the shielding circuit SH4. In one embodiment not shown here, there may be other conductors used for grounding between the antenna AN1, the antenna AN2, the antenna AN3, and the antenna AN4 and the shielding circuit SH1, the shielding circuit SH2, the shielding circuit SH3, and the shielding circuit SH4.

In one embodiment, when the antenna AN1, the antenna AN2, the antenna AN3, and the antenna AN4 are used for signal transmission, and there is no other conductor used for electrical transmission between the antenna AN1, the antenna AN2, the antenna AN3, and the antenna AN4 and the shielding circuit SH1, the shielding circuit SH2, the shielding circuit SH3, and the shielding circuit SH4, the grounded shielding circuit SH1, shielding circuit SH2, shielding circuit SH3, and shielding circuit SH4 may be considered as electromagnetic interference shielding layers. As a result, during signal transmission, these shielding circuits may reduce the interference of the transmitted signal with other components, and/or reduce the possibility of the transmitted signal being interfered with by other components, thereby improving signal quality.

In one embodiment, the shielding circuit SH1, the shielding circuit SH2, the shielding circuit SH3, and the shielding circuit SH4 are not disposed in a sheet-like or full-plane arrangement. In one embodiment, along a direction parallel to the thickness of the first circuit structure 100, the pattern of the antenna AN1, the antenna AN2, the antenna AN3, and the antenna AN4 is substantially the same as or similar to the pattern of the shielding circuit SH1, the shielding circuit SH2, the shielding circuit SH3, and the shielding circuit SH4. Therefore, the metal pattern densities on both sides of the first core layer 111 (for example, the upper side or the lower side in FIG. 1D) may be relatively close. As a result, the possibility of warpage caused by excessive difference in thermal expansion due to the large difference in metal pattern density between the two sides may be reduced during the manufacturing process of the electronic packaging structure 100. In one embodiment, the shielding circuit SH1, the shielding circuit SH2, the shielding circuit SH3, and the shielding circuit SH4 may serve the function of resonance effect between the antenna AN1, the antenna AN2, the antenna AN3, and the antenna AN4.

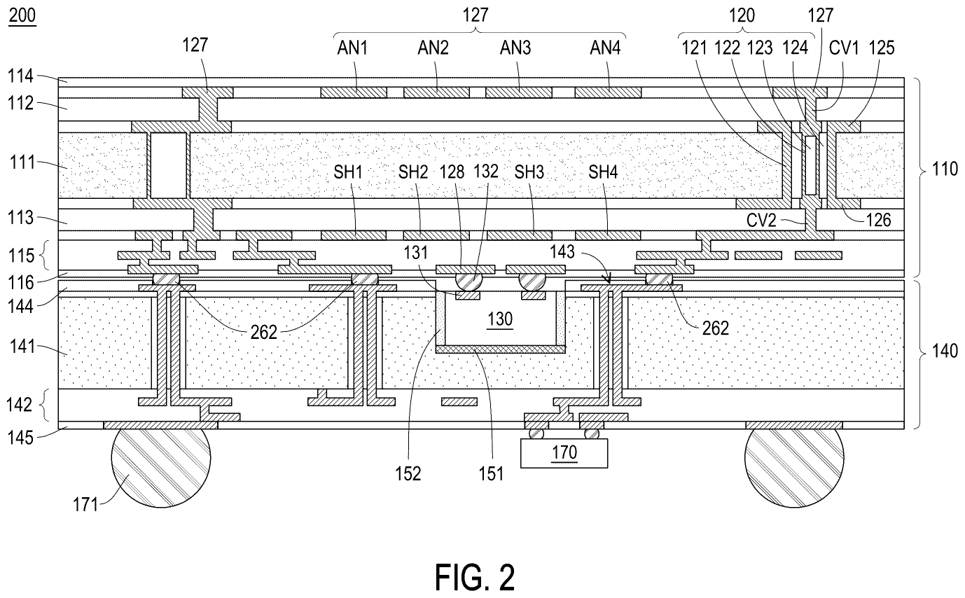

FIG. 2 is a schematic view showing the electronic packaging structure according to the second embodiment of the disclosure.

Referring to FIG. 2, an electronic packaging structure 200 is provided. Referring to FIG. 2, the electronic packaging structure 200 includes the first circuit structure 110, the second circuit structure 140, and the first electronic component 130. The first electronic component 130 is located between the first circuit structure 110 and the second circuit structure 140. At least one of the first circuit structure 110 and the second circuit structure 140 (for example, the second circuit structure 140) has the cavity 150. The first electronic component 130 is embedded in the cavity 150, and may be encapsulated between the first circuit structure 110 and the second circuit structure 140. The first circuit structure 110 includes the coaxial conductive via 120. The coaxial conductive via 120 includes the inner conductive layer 122, the outer conductive layer 121, and the first dielectric layer 124. The first dielectric layer 124 is located between the inner conductive layer 122 and the outer conductive layer 121. The electronic packaging structure 200 is similar to the electronic packaging structure 100, except that the first circuit structure 110 and the second circuit structure 140 are bonded by a different method.

In one embodiment, conductive terminals 262 are disposed in at least one opening 129 in the first circuit structure 110 and at least one opening 161 in the second circuit structure 140. The conductive terminals 262 bond and electrically connect the first circuit structure 110 and the second circuit structure 140.

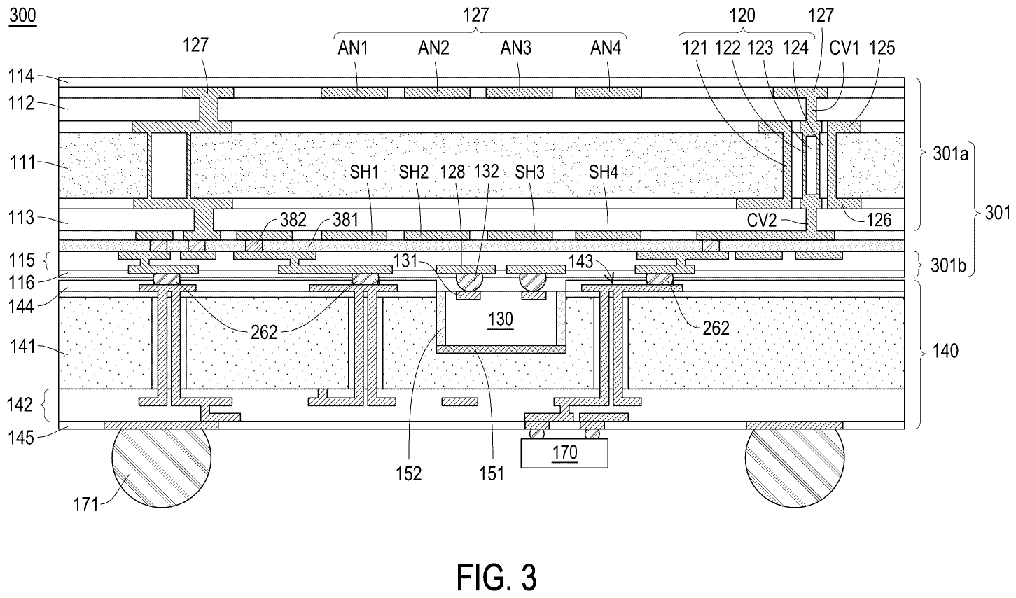

FIG. 3 is a schematic view showing the electronic packaging structure according to the third embodiment of the disclosure.

Referring to FIG. 3, an electronic packaging structure 300 is provided. Referring to FIG. 3, the electronic packaging structure 300 includes a first circuit structure 301, the second circuit structure 140, and the first electronic component 130. The first electronic component 130 is located between the first circuit structure 301 and the second circuit structure 140. At least one of the first circuit structure 301 and the second circuit structure 140 (for example, the second circuit structure 140) has the cavity 150. The first electronic component 130 is embedded in the cavity 150, and may be encapsulated between the first circuit structure 301 and the second circuit structure 140. The first circuit structure 301 includes the coaxial conductive via 120. The coaxial conductive via 120 includes the inner conductive layer 122, the outer conductive layer 121, and the first dielectric layer 124. The first dielectric layer 124 is located between the inner conductive layer 122 and the outer conductive layer 121. The electronic packaging structure 300 is similar to the electronic packaging structure 100 or the electronic packaging structure 200, except that the first circuit structure 301 of the electronic packaging structure 300 is different from the first circuit structures 110 of the electronic packaging structures 100 and 200.

The first circuit structure 301 includes a first sub-structure 301a and a second sub-structure 301b. The first sub-structure 301a and the second sub-structure 301b may be considered as different structures structurally. For example, in the manufacturing process of the electronic packaging structure 300, the first sub-structure 301a and the second sub-structure 301b may be formed or provided separately, and then combined with each other afterwards.

In one embodiment, the first sub-structure 301a includes a first core layer 111, a corresponding wiring layer and a corresponding insulation layer located on the upper side and the lower side of the first core layer 111, and an insulation layer 114 located on the outermost side of the first circuit structure 301. The first core layer 111 may include at least one coaxial conductive via 120 penetrating the first core layer 111. In one embodiment, the coaxial conductive via 120 includes the outer conductive layer 121, the first dielectric layer 124, the second dielectric layer 123, and the inner conductive layer 122. In one embodiment, the first core layer 111 may further include other conductive vias, which may include solid metal pillars or hollow metal pillars with an insulating material filled in the hollow metal pillars, but the disclosure is not limited thereto.

In one embodiment, the second sub-structure 301b includes a redistribution layer 115, and an insulation layer 116 located on the outermost side of the first circuit structure 301.

In one embodiment, the second sub-structure 301b may be called an interposer, but the disclosure is not limited thereto.

In one embodiment, the insulation layers 114 and 116 located on the outermost side of the first circuit structure 301 may be called solder masks, which are used to reduce or decrease oxidation and prevent forming a solder bridge between closely spaced pads. The insulation layers 114 and 116 located on the outermost side of the first circuit structure 301 may include epoxy resin.

The first sub-structure 301a and the second sub-structure 301b may be bonded by conductive adhesive 382. A filling layer 381 may fill the bonding gap between the bottom surface of the first sub-structure 301a and the top surface of the second sub-structure 301b.

In one embodiment, the conductive adhesive 382 may include metal alloy, solder paste, silver adhesive, or other suitable conductive adhesive, but the disclosure is not limited thereto.

In one embodiment, the filling layer 381 includes underfill, but the disclosure is not limited thereto.

In one embodiment, the aforementioned coaxial conductive via (for example, the coaxial conductive via 120) may be called a coaxial conductive component. In one embodiment, the aforementioned coaxial conductive via (for example, the coaxial conductive via 120) may be considered as a conductive via that includes different wiring layers (for example, the outer conductive layer 121 or the inner conductive layer 122).

In the above embodiments, the conductive layer or wiring layer may be a single-layer or multi-layer structure. In the case where the conductive layer or wiring layer is a multi-layer structure, there may be no insulating material or dielectric material between the multi-layer structures. Additionally, in terms of structure, in the case where the conductive layer or wiring layer is a multi-layer structure, the multi-layer structure may still be represented by the same term and/or reference numeral (but is not limited thereto) even if the multi-layer structure is formed by a different process. Furthermore, in the case where the conductive layer or wiring layer is a multi-layer structure, the interfaces between corresponding film layers in the multi-layer structure may be omitted in the illustration.

In the above embodiments, the insulation layer or dielectric layer may be a single-layer or multi-layer structure. In the case where the insulation layer or dielectric layer is a multi-layer structure, there may be no conductive material between the multi-layer structures. Additionally, in terms of structure, in the case where the insulation layer or dielectric layer is a multi-layer structure, the multi-layer structure may still be represented by the same term and/or reference numeral (but is not limited thereto) even if the multi-layer structure is formed by a different process. Furthermore, in the case where the insulation layer or dielectric layer is a multi-layer structure, the interfaces between corresponding film layers in the multi-layer structure may be omitted in the illustration.

In the above embodiments, the corresponding wiring in one wiring layer may be electrically connected to the corresponding wiring in another wiring layer by a corresponding conductive component (for example, conductive via). In other words, unless specifically stated or implied, even though the electrical connection between the corresponding wiring in one wiring layer and the corresponding wiring in another wiring layer may not be illustrated in the drawing, the corresponding wiring in one wiring layer and the corresponding wiring in another wiring layer may still be electrically connected to each other by a conductive component that is not illustrated in the drawing or cross-section.

In summary, in the electronic packaging structure, the electronic component is located between the first circuit structure and the second circuit structure, and at least part of the electronic component may be located in the cavity of one of the circuit structures (for example, the second circuit structure). Therefore, the electronic component is properly protected, which reduces the possibility of damage or deterioration of the electronic component and improves the quality of the electronic packaging structure.

On the other hand, one of the circuit structures (for example, the first circuit structure) of the electronic packaging structure may further include a coaxial conductive via. The electronic component may be electrically connected to the corresponding wiring (for example, antenna) by the coaxial conductive via. Therefore, the signal interference can be reduced and/or the signal quality can be improved.

What is claimed is:

1. An electronic packaging structure, comprising:
a first circuit structure;
a second circuit structure; and
a first electronic component located between the first circuit structure and the second circuit structure,
wherein at least one of the first circuit structure and the second circuit structure has a cavity, and the first electronic component is embedded in the cavity.

2. The electronic packaging structure according to claim 1, wherein the second circuit structure further comprises a conductive core layer.

3. The electronic packaging structure according to claim 1, further comprising:
a thermal interface material filled in the cavity and in contact with the first electronic component.

4. The electronic packaging structure according to claim 1, further comprising:
a second electronic component disposed on a bottom surface of the second circuit structure.

5. The electronic packaging structure according to claim 1, wherein the first circuit structure comprises a first redistribution layer;
the second circuit structure comprises a second redistribution layer; and
the first redistribution layer and the second redistribution layer face a same side of the electronic packaging structure.

6. The electronic packaging structure according to claim 1, further comprising:
a conductive connecting component located between the first circuit structure and the second circuit structure and electrically connecting the first circuit structure and the second circuit structure.

7. The electronic packaging structure according to claim 1, wherein the first circuit structure comprises a coaxial conductive via, and the coaxial conductive via comprises:
an inner conductive layer;
an outer conductive layer; and
a first dielectric layer located between the inner conductive layer and the outer conductive layer.

8. The electronic packaging structure according to claim 7, wherein the outer conductive layer is grounded.

9. The electronic packaging structure according to claim 7, wherein the coaxial conductive via further comprises a second dielectric layer, and the inner conductive layer is located between the first dielectric layer and the second dielectric layer.

10. The electronic packaging structure according to claim 7, wherein the first circuit structure further comprises a first sub-structure and a second sub-structure electrically connected to the first sub-structure, wherein the first sub-structure comprises the coaxial conductive via, and the second sub-structure comprises a first redistribution layer.
